(19) United States
(12) Patent Application Publication
(10) Pub. No.: US 2012/0119830 A1
(43) Pub. Date: May 17, 2012

(54) MODULE FOR MODULATION AND AMPLIFICATION

(75) Inventors: Anthony Sayers, Herts (GB); Paul Anthony Moore, Seaford (GB)

(73) Assignee: NXP B.V., Eindhoven (NL)

(21) Appl. No.: 13/201,776

(22) PCT Filed: Feb. 17, 2010
(86) PCT No.: PCT/IB10/50699

§ 371 Date: Nov. 16, 2011

(30) Foreign Application Priority Data
Feb. 17, 2009 (EP) 09153010.5

(51) Int. Cl. H03F 3/68

(52) U.S. Cl. 330/124 R

(57) ABSTRACT

The present application relates to a module comprising at least two amplifiers. The first amplifier is configured to amplify an inphase signal. The second amplifier is configured to amplify a quadrature signal. The module comprises a combiner configured to combine the at least two amplified signals. The module comprises a phase reversal unit configured to provide at least two amplified signals comprising a maximum phase difference of 2 p.

### TECHNICAL FIELD

The present application relates to a module comprising at least two amplifiers. More particularly, the first amplifier is configured to amplify an inphase signal and the second amplifier is configured to amplify a quadrature signal. The present application relates also to a transmitter comprising said module and to a mobile phone comprising said transmitter.

### BACKGROUND OF THE INVENTION

Many consumer electronics, such as mobile devices and other connectivity applications comprise transmitters for sending information to another entity. For achieving a high data transfer rate, in modern radio systems, such as Universal Mobile Telecommunications System (UMTS), e.g. used in 3G phones, or Orthogonal Frequency Division Multiplex (OFDM) systems, e.g. used in Wireless Ethernet Compatibility Alliance (WiFi) and television applications, the amplitude component as well as the phase component of the signal to be transmitted can be modulated.

However, issues may occur due to the employed amplifiers. Typically, efficient amplifiers require an input signal with an approximately constant amplitude. According to prior art, it is possible to modulate the phase of the input signal and to modulate the amplitude using the power supply of the amplifier. Another prior art solution is to use two phase-modulated signals comprising a phase difference of 90 degree or

$$\frac{π}{2} .$$

These signals can be individually amplified using two amplifiers and combined resulting in the desired phase and amplitude modulated signal.

Referring to FIG. 1, an embodiment of such a power combiner structure according to prior art is shown. The present structure comprises a first amplifier 2.1 and a second amplifier 2.2 as well as a combiner 4. The amplifiers 2.1 and 2.2 can be supplied with a supply voltage via the input terminals 12.1 and 12.2. An inphase component or inphase signal 6 can be amplified by the first amplifier 2.1 while a quadrature component or quadrature signal 6 can be amplified by the second amplifier 2.2. The provided combiner 4 can be configured to combine the two amplified signals. As a result, the desired phase and amplitude modulated signal 10 can be obtained.

However, the problem with the solution according to prior art described above is that there is no means of generating quadrature components that have phases opposing the carrier signals. For, example there is no means of generating a signal that is 180 degrees out of phase with the inphase carrier. Thus, the output of the circuit according to FIG. 1 would be limited to modulation with phase variation over solely one quadrant, i.e. 90 degrees or

$$\frac{π}{2} .$$

### SUMMARY OF THE INVENTION

It is one object of the present application to provide a module enabling an improved modulation and amplification structure. Another object is to increase the possible phase variation range of the modulation. A further object is to provide an amplification module having an improved efficiency.

These and other objects are addressed by a module comprising at least two amplifiers. The first amplifier is configured to amplify an inphase signal. The second amplifier is configured to amplify a quadrature signal. The module comprises a combiner configured to combine the at least two amplified signals. The module comprises a phase reversal unit configured to provide at least two amplified signals comprising a maximum phase difference of 2 p.

The present module can be employed in any transmitter which processes phase and amplitude modulated signals. The module may be implemented in the analogue domain, the digital domain or partially in the digital and analogue domain.

According to the present application, the module comprises a first amplifier and a second amplifier, in particular efficient power amplifiers. It shall be understood that, according to other variants of the present application, the module may comprise also three and more amplifiers. While the first amplifier is configured to amplify an inphase signal to a desired transmitting power, the second amplifier is configured to amplify a quadrature signal to a desired transmitting power. Both signals may comprise the information to be transmitted.

The amplified signals are combined by an arranged combiner to a desired output signal. More particularly, the power combiner may be configured to combine the amplified signals such that the resulting signal is the desired phase and amplitude modulated signal.

It is found according to the present application that the phase variation range, and thus, the data rate can be increased, if at least one phase reversal unit is used. In particular, the phase reversal unit, such as a suitable signal modulator, is configured to provide at least two amplified signals comprising a maximum phase difference of 2 p. Since the possible phase difference is not limited to one quadrant or

$$\frac{π}{2} ,$$

but may be also p,

$$\frac{3 π}{2}$$

or at most 2 p, the efficiency of the present module may be significantly increased.

According to another embodiment, the inphase signal and the quadrature signal may comprise an approximately constant amplitude. It may be advantageous to use signals with a constant amplitude since high efficient amplifiers can be used as first and second amplifier.

Furthermore, according to another embodiment of the present application, at least one of the amplifiers may be configured to control the amplitude of the amplified signal by a power supply of the amplifier. The power output of the amplifier may be controllable via the power supply. A desired output amplitude can be obtained with simple means. It shall be understood that according to other variants of the present application, all employed amplifiers may be controllable via their power supplies.

For generating the desired phase and amplitude modulated output signal, the combiner may be configured, according to an embodiment, to combine the at least two amplified signals such that the combined output signal is a non-constant output signal.

In another embodiment, the phase reversal unit may be arranged previously to the at least two amplifiers. In this case, the input signals of the amplifiers can be preprocessed such that the desired phase variation over four quadrants is obtained. A subsequent processing unit can be omitted.

What is more, the phase reversal unit can be formed as a first phase reversal unit and a second phase reversal unit. In particular, in both signal branches, the inphase signal branch and the quadrature signal branch, a phase reversal unit can be implemented. Each signal can be independently controlled and modulated by the respective two phase reversal units which can be arranged previously to the respective amplifiers. It shall be understood that a suitable control device, like a microprocessor can be provided for controlling the phase reversal units.

According to a further embodiment of the present application, the phase reversal unit may be formed as a phase shift keying modulator. A phase shift keying (PSK) modulator may be particular suitable for reversing the phase of the respective signals and can be implemented with simple means. The resulting input signals of the amplifiers may be binary PSK signals comprising a maximum phase difference of 2 p.

As an alternative, the phase reversal unit can be formed according to another embodiment of the present application as two additional amplifiers. The two additional amplifiers can be arranged in parallel to the previously mentioned amplifiers. In other words, four parallel amplifiers and respective signal braches may be provided. The resulting amplified signals can be combined by a suitable combiner having four input terminals. The input signals of the at least four amplifiers may be completely unmodulated.

Furthermore, each of the four amplifiers may be configured to amplify a four-phase carrier input signal. In other words, each amplifier may receive a signal being 90 degrees phase shifted. For instance, a positive and negative inphase component as well as a positive and negative quadrature component can be received by the respective amplifiers. It shall be understood that merely two amplifiers may be activated at the same time. It shall be further understood that a suitable control device can be arranged for controlling the respective amplifiers.

For obtaining an efficient system with reduced power consumption, the combiner may comprise at least one impedance inverter arranged for each amplifier. The impedance converter may be arranged in each input signal path corresponding to each amplifier. It is found that an inverter may only comprise such an impedance inverter without any further components, like inductor or capacitors for achieving the desired combined phase and amplitude modulated signal with an increased efficiency.

According to a further embodiment of the present application, the impedance inverter may comprise a length of approximately a quarter of the wavelength. Such an impedance inverter can be simply realized.

Another aspect of the present application is a transmitter comprising the above-described module. For instance, the transmitter can be employed in cellular, mobile, connectivity applications and the like. The transmitter is particular suitable for application wherein the modulation comprises a non-constant envelope.

A further aspect of the present application is mobile phone comprising the above-described transmitter.

These and other aspects of the present patent application become apparent from and will be elucidated with reference to the following Figures. The features of the present application and of its exemplary embodiments as presented above are understood to be disclosed also in all possible combinations with each other.

### BRIEF DESCRIPTION OF THE DRAWINGS

In the Figures show:

FIG. 1 an embodiment according to prior art,

FIG. 2 a first embodiment of the module according to the present application,

FIG. 3 an embodiment of a combiner structure according to the present application,

FIG. 4 a second embodiment of the module according to the present application.

Like reference numerals in different Figures indicate like elements.

### DETAILED DESCRIPTION OF THE DRAWINGS

In the following detailed description of the present application, exemplary embodiments of the present application will describe and point out an improved amplification module, which may provide for a higher efficiency and a larger possible phase variation range of the modulation.

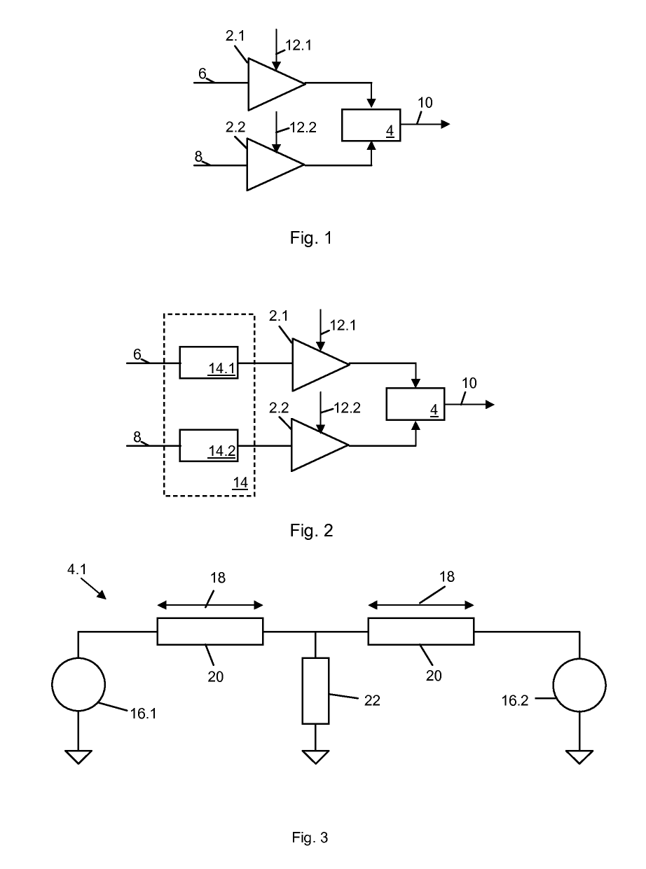

FIG. 2 shows a first simplified embodiment of the module according to the present application. As can be seen from FIG. 2, a first amplifier 2.1, a second amplifier 2.2 and one combiner 4 are provided. It may be possible to use a Wilkinson power combiner. Another implementation of the combiner will be elucidated subsequently with the aid of FIG. 3.

As amplifiers 2.1 and 2.2 in the above design power amplifiers can be used high efficient power amplifiers, like class D or E amplifiers. Furthermore, the power output of the provided amplifiers 2.1 and 2.2 may be controllable via a power supply (not shown) using the input terminals 12.1 and 12.2.

Referring to FIG. 2, previously to the amplifiers 2.1 and 2.2, a phase reversal unit 14 is arranged. More particularly, the present phase reversal unit 14 comprises a first phase reversal unit 14.1 and a second phase reversal unit 14.2. For instance, each phase reversal unit can be formed as a PSK modulator. Then the input signal of each amplifier 2.1 and 2.2 is a binary PSK signal. More particularly, the PSK signals may comprise a phase difference of at most 2 p to each other. It shall be understood that, according to other variants of the present application, other modulators providing the desired phase variation range and modulated signals with a constant slope can be also used.

It shall be further understood that because the output modulated signal may have a limited bandwidth, the amplitude of the inphase and quadrature components may vary continuously. If the sign of these components changes, the amplitude change of the required signal may be small. Errors induced by the change of sign may also not affect the total output 10 greatly.

In FIG. 3, a simplified embodiment of a combiner structure according to the present application. More particularly, the depicted combiner 4.1 is in communication with the output 16.1 of the first amplifier 2.1 and the output 16.2 of the second amplifier 2.2. It shall be understood that according to variants of the present module having more than two amplifiers, like four amplifiers, the combiner may comprise a respective number of connections to the outputs of these amplifiers.

Furthermore, a load 22 can be provided with the combined signal using the two arranged impedance inverters 20. Thereby, the impedance converters 20 may comprise a length 18 of approximately a quarter of the wavelength. The resulting output signal may be a signal having a non-constant envelope.

Further components, like inductors and/or capacitors at the power amplifier outputs 16.1 and 16.2, have been omitted. These and further elements can be omitted since such elements would be inductive or capacitive depending on the phase of the opposite amplifier, which may be unknown. Nevertheless, the combiner 4.1 may work as long as the amplifiers outputs 16.1 and 16.2 can be modeled as voltage sources, as shown in FIG. 3. This may be so if the outputs 16.1 and 16.2 of the amplifiers are heavily saturated. The efficiency of the described combiner 4.1 is significantly increased. For instance, compared to a Wilkinson combiner, the efficiency can be increased up to 50%.

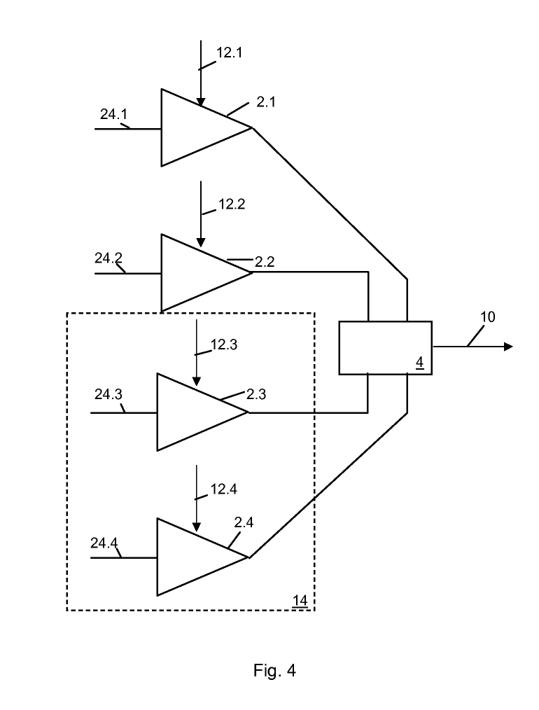

FIG. 4 shows a second simplified embodiment of the module according to the present application. In the shown embodiment, besides the already known components, i.e. the two amplifiers 2.1 and 2.2 and the combiner 4, two further amplifiers 2.3 and 2.4 are provided.

The two further amplifiers 2.3 and 2.4 may act as the phase reversal unit 14. More particularly, the four amplifiers 2.1 to 2.4 may receive four signals, e.g. the positive inphase component 24.1, the positive quadrature component 24.2, the negative inphase component 24.3 and the negative quadrature component 24.4. In other words, at least two amplified signals may comprise a maximum phase difference of 2 p.

The advantage to the above-described module is that the input signals to the amplifiers 2.1 to 2.4 may be completely unmodulated. Furthermore, merely two of the four amplifiers 2.1 to 2.4 may be used at any time.

Furthermore, it is readily clear for a person skilled in the art that the logical blocks in the schematic block diagrams at least partially be implemented in electronic hardware and/or computer software, wherein it depends on the functionality of the logical block and on design constraints imposed on the respective devices to which degree a logical block, a is implemented in hardware or software. The presented logical blocks may for instance be implemented in one or more digital signal processors, application specific integrated circuits, field programmable gate arrays or other programmable devices. The computer software may be stored in a variety of storage media of electric, magnetic, electro-magnetic or optic type and may be read and executed by a processor, such as for instance a microprocessor. To this end, the processor and the storage medium may be coupled to interchange information, or the storage medium may be included in the processor.

1. A module, comprising:
at least two amplifiers,
wherein the first amplifier is configured to amplify an inphase signal,
wherein the second amplifier is configured to amplify a quadrature signal,
a combiner configured to combine the at least two amplified signals, and
a phase reversal unit configured to provide at least two amplified signals comprising a maximum phase difference of 2 p.

2. The module according to claim 1, wherein the inphase signal and the quadrature signal comprises an approximately constant amplitude.

3. The module according to claim 1, wherein at least one of the amplifiers is configured to control the amplitude of the amplified signal by a power supply of the amplifier.

4. The module according to claim 1, wherein the combiner is configured to combine the at least two amplified signals such that the combined output signal is a non-constant output signal.

5. The module according to claim 1, wherein the phase reversal unit is arranged previously to the at least two amplifiers.

6. The module according to claim 2, wherein the phase reversal unit is formed as a first phase reversal unit and a second phase reversal unit.

7. The module according to claim 2, wherein the phase reversal unit is formed as a phase shift keying modulator.

8. The module according to claim 1, wherein the phase reversal unit is formed as two additional amplifiers.

9. The module according to claim 8, wherein each of the four amplifiers is configured to amplify a four-phase carrier input signal.

10. The module according to claim 1, wherein the combiner comprises at least one impedance inverter arranged for each amplifier.

11. The module according to claim 10, wherein the impedance inverter comprises a length of approximately a quarter of the wavelength.

12. A transmitter comprising the module according to claim 1.

13. A mobile phone comprising the transmitter according to claim 9.
